(19) United States
(12) Patent Application Publication
(10) Pub. No.: US 2002/0146911 A1
(43) Pub. Date: Oct. 10, 2002

(54) Semiconductor device and method of manufacturing the same

(75) Inventors: Seiji Muranaka, Hyogo (JP); Hiroshi Tanaka, Hyogo (JP); Naoki Yokoi, Hyogo (JP); Yasuhiro Asaoka, Hyogo (JP); Toshihiko Nagai, Osaka (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/963,054

(22) Filed: Sep. 26, 2001

(30) Foreign Application Priority Data
Apr. 4, 2001 (JP) 2001-105939 (P)

(51) Int. Cl. H01L 21/302; H01L 21/461

(52) U.S. Cl. 438/745; 438/751; 438/750; 438/749

(57) ABSTRACT

A method of manufacturing a semiconductor device, having a resist-removing step which is improved so as not to etch a peripheral material and damage the peripheral material is provided. A resist pattern is formed on a substrate. Using the resist pattern as a mask, the substrate is etched. A surface-deteriorated layer of the resist pattern is removed by a first chemicals treatment. A bulk portion of the resist pattern is removed by a second chemicals treatment.

### BACKGROUND OF THE INVENTION

1. Field of the Invention

The present invention generally relates to a method of manufacturing a semiconductor device, and more particularly to a method of manufacturing a semiconductor device including a resist-removing step which is improved so as not to etch a peripheral material and damage the peripheral material.

The present invention further relates to a semiconductor device resulting from such a method.

2. Description of the Background Art

FIG. 8 schematically illustrates a conventional manufacturing process of a semiconductor device.

A manufacturing process of a semiconductor device includes repeated steps of depositing a required type of film, then forming a resist pattern, and then through the etching process, forming a desired film pattern.

Removal of a resist pattern after etching is conventionally performed by dry ashing using oxygen plasma or the like. After ashing, in order to remove the resist residue resulting from etching and ashing and the polymer adhered onto the pattern, a chemicals treatment is performed. Such a process flow is generally performed.

Although such dry ashing is a process commonly used, it cannot be applied in some cases depending on the material or process to be used. Further, since the ashing process damages a peripheral material, an alternative process is required in some cases.

An example where the ashing process cannot be applied includes the step in which a low dielectric constant insulating film material (referred to “Low-k material” hereafter), which is now increasingly used, is exposed. Additional Low-k material includes, for example, silicate type material which is inorganic SOG (Spin On Glass), halogen siloxane type material, organic SOG, fluorocarbon which is a polymer material, polynaphthalene and the like.

Low-k material has been recently used as an interlayer insulating film covering the interconnection in order to reduce capacitance between interconnections. Some among Low-k material have a structure of an organic material. When such a material is used, however, it is etched during dry ashing, or has its film structure changed. Therefore, unfortunately, a normal oxygen ashing cannot be performed.

Further, in order to prevent the damage of the peripheral material during dry ashing, the necessity of an alternative process is realized. An example includes the resist-removing step performed after etching of a transistor gate. One of the problems raised by ashing in the resist-removing step is that it damages a gate insulating film, it damages the silicon substrate in the source/drain regions, and that it undesirably oxidizes a gate material, all leading to an increased resistance. This results in the degradation of a transistor.

### SUMMARY OF THE INVENTION

The present invention is made to solve the above problems, and its object is to provide a method of manufacturing a semiconductor device, having a resist-removing step which is improved so as not to etch Low-k material and not to change a film structure.

Another object of the present invention is to provide a method of manufacturing a semiconductor device, having a resist-removing step without etching a peripheral material and damaging the peripheral materiel.

A further object of the present invention is to provide a semiconductor device resulting from such a manufacturing method.

In a method of manufacturing a semiconductor device according to the first aspect of the present invention, a resist pattern is first formed on a substrate (a first step). Using the resist pattern as a mask, the above mentioned substrate is etched (a second step). A first chemicals treatment is performed to remove a surface-deteriorated layer of the resist pattern (a third step). A second chemicals treatment is performed to remove the bulk portion of the resist pattern (a fourth step).

In a method of manufacturing a semiconductor device according to the second aspect of the present invention, the aforementioned first chemicals treatment is performed with chemicals including at least an organic solvent, a compound including NH₄F or amine, and water.

In a method of manufacturing a semiconductor device according to the third aspect of the present invention, the aforementioned second chemicals treatment is performed with chemicals including an organic solvent and a compound including amine, and not including water.

In a method of manufacturing a semiconductor device according to the fourth aspect of the present invention, the aforementioned substrate has a structure formed by stacking metal, polysilicon and an insulating film.

In a method of manufacturing a semiconductor device according to the fifth aspect of the present invention, the aforementioned substrate has a structure formed of a conductive film for lower electrode, a capacitance insulating film and a conductive film for upper electrode.

In a method of manufacturing a semiconductor device according to the sixth aspect of the present invention, the aforementioned substrate has a structure in which an interlayer insulating film is formed on a capacitor formed of a lower electrode, a capacitance insulating film and an upper electrode, and the aforementioned third step is a step of etching the aforementioned interlayer insulating film to form a connection hole reaching to the upper electrode.

In a method of manufacturing a semiconductor device according to the seventh aspect of the present invention, the aforementioned first and second steps include a step of forming an interconnection using a resist pattern.

In a method of manufacturing a semiconductor device according to the eighth aspect of the present invention, the aforementioned first and second steps include the steps of forming an interlayer insulating film to cover an interconnection, and forming a contact hole in the aforementioned interlayer insulating film.

In a method of manufacturing a semiconductor device according to the ninth aspect of the present invention, the aforementioned substrate has such a structure in which an interlayer insulating film is formed above a buried interconnection with a protection film formed thereon, and the aforementioned second step is an etching step for forming a contact hole reaching to the protection film on the buried interconnection.

In a method of manufacturing a semiconductor device according to the tenth aspect of the present invention, the aforementioned interlayer insulating film is an organic polymer film.

In a method of manufacturing a semiconductor device according to the eleventh aspect of the present invention, a resist pattern is first formed on a substrate. Using the aforementioned resist pattern as a mask, ions are implanted into the surface of the substrate. A first chemicals treatment is performed to remove a surface-deteriorated layer on the resist pattern. A second chemicals treatment is performed to remove a bulk portion of the resist pattern.

A semiconductor device in accordance with the twelfth aspect of the present invention results from the following steps of:

(1) forming a resist pattern on a substrate;

(2) etching the substrate using the resist pattern as a mask;

(3) performing a first chemicals treatment for removing a surface-deteriorated layer of the resist pattern;

(4) performing a second chemicals treatment for removing a bulk portion of the resist pattern.

As described above, the present invention allows for resist-removal without etching a peripheral material and damaging the peripheral material. Accordingly, a semiconductor device with excellent electric characteristics can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of a semiconductor device, showing main steps of a method of manufacturing a semiconductor device in accordance with a first embodiment.

FIG. 2 is a cross sectional view of a semiconductor device in accordance with another example of the first embodiment.

FIG. 3 is a cross sectional view of semiconductor device, showing a main step of a method of manufacturing a semiconductor device in accordance with a second embodiment.

FIG. 4 is a cross sectional view of a semiconductor device, showing a main step of a method of manufacturing a semiconductor device in accordance with a third embodiment.

FIG. 5 is a cross sectional view of a semiconductor device showing another example of the third embodiment.

FIG. 6 is a cross sectional view of a semiconductor device showing a further example of the third embodiment.

FIG. 7 is a cross sectional view of a semiconductor device showing a still further example of the third embodiment.

FIG. 8 is a diagram showing conventional steps of a method of manufacturing a semiconductor device.

### DESCRIPTION OF THE PREFERRED EMBODIMENTS

Embodiments of the present invention will be described in the following with reference to the drawings.

(First Embodiment)

Usually, the surface of a resist after etching and ashing is deteriorated by the damage due to a dry process, to a substance which is difficult to be removed by chemicals. The bulk portion, which is not a surface layer, is less deteriorated. Therefore, it is necessary to perform separate chemicals treatments having respective removabilities for the surface-deteriorated layer and the bulk portion. The present embodiment provides a cleaning process of removing a resist only by chemicals treatment and without dry ashing, wherein a chemicals treatment with strong residue-removability for removing the surface-deteriorated layer resulting from dry process such as etching and the like, and a chemicals treatment with strong removability of the bulk resist are continuously performed. This continuous treatment with two chemicals enables the complete removal of resist, without performing ashing.

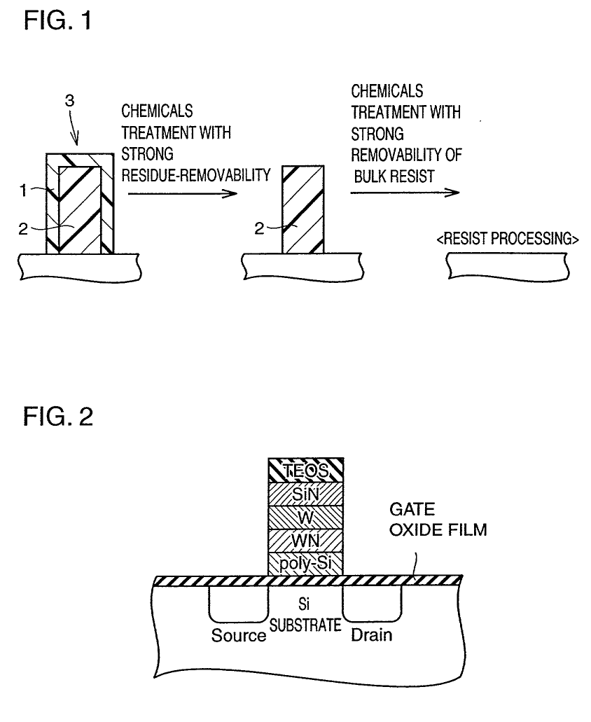

FIG. 1 is a cross sectional view of a semiconductor device showing a resist-removing process in accordance with the present embodiment. The resist-removing process includes the step of removing a surface-deteriorated layer 1, and the subsequent step of removing a bulk resist 2. These steps are performed with different chemicals.

With only a single chemicals treatment with strong residue-removability for removing surface-deteriorated layer 1, resist 3 cannot be completely removed. Further, with only a single chemicals treatment with strong removability of bulk resist 2, resist 3 cannot be completely removed as well. Still further, even if the chemicals treatment with strong removability of bulk resist 2 is performed, and thereafter continuously, the chemicals treatment with strong residue-removability for removing surface-deteriorated layer 1 is performed in this order, resist 3 cannot be completely removed.

In other words, with only a single treatment with either one of the chemicals, the resist cannot be fully removed.

Furthermore, when the chemicals treatment with strong removability of bulk resist 2 is first performed, surface-deteriorated layer 1 is not removed. Therefore, as the portion of underlying bulk resist 2 is not permeated by the chemicals, bulk resist 2 remains on the surface of the wafer even after the chemicals treatment. Thereafter, even if the chemicals treatment with strong residue-removability for removing surface-deteriorated layer 1 is continuously performed, the bulk resist is not completely removed. Therefore, the continuous treatments in the above noted order cannot remove the resist.

It has been found that resist 3 can be completely removed by initially performing the chemicals treatment with strong residue-removability for removing surface-deteriorated layer 1, followed by the chemicals treatment with strong removability of bulk resist 2.

An example of chemicals with strong residue-removability (a first chemicals) includes stripping solution including at least an organic solvent, a compound including NH₄F or amine, and water. Here, a preferable organic solvent is solvent with a great intramolcular polarization, such as ethylene glycol, dimethyl formamide, dimethyl sulfoxide, N,N-dimethyl imidazolidinone, N-methyl-2-pyrolidone. This is because solubility for inorganic residue is stronger, if intramolecular polarization is great. Further, in addition to the above, the first chemicals may further include an additive for increasing permeability of chemicals (so-called wettability) or for increasing corrosion resistance of an interconnection and the like. An example of additive includes chelate agent having a function of removing a metal, for example catechol and the like.

The mechanism by which chelate agent exhibits a metal removing function is as follows. An unpaired electron pair of chelate agent itself is bonded with d orbit or f orbit of a metal ion with cavity, thereby forming a big molecular structure which looks like metal ion and is solved in solvent such as water. This can prevent production of haogenide, hydroxide and the like.

The compound including NH₄F or amine mentioned herein is a substance which mainly contributes to the reaction of removing an inorganic material such as the surface-deteriorated layer.

An example of chemicals with strong removability of the bulk resist (a second chemicals) includes stripping solution including an organic solvent and a compound including amine, and not including water. If water is included, the removability for the resist deteriorated layer increases, while solubility for an organic substance decreases. Then, in order to increase the removability of the bulk resist which is an organic substance, water may not be included. However, in order to retain a little removability of residue, chemicals not perfectly water-free but containing a small amount of water may be used, which water amount is smaller than that in “chemicals with strong residue-removability (a first chemicals)”. It is noted that as the organic solvent used for the second chemicals, the one similar to the first chemicals may be used. Further, as a compound including amine used for the second chemicals, hydroxylamine, monoethanolamine, dimethylamine and the like is preferred. When water-free chemicals being used, the solubility of bulk resist which is an organic substance increases.

FIG. 2 is a cross sectional view of a metal gate made of a metal material such as W, WN, Ti, TiN, polysilicon, SiN, and SiO₂ or the like. In a future device, it is expected that a metal gate using a metal material such as W, WN, Ti, TiN other than a conventional polysilicon (poly-Si) or WSi will be used to reduce the gate delay.

The resist-removing process using the continuous treatment with two chemicals in accordance with the present embodiment is preferably applied to the resist-removal after the etching step for forming a gate shape, or after the step of ion implantation into a well region or source/drain regions. The method in accordance with the present embodiment prevents degradation of a gate insulating film and degradation due to oxidation of a metal gate material does not occur. Therefore, deteriorated reliability of oxide film caused thererby can be prevented, and hence enabling prevention of degradation of the transistor characteristics.

(Second Embodiment)

The resist-removing process using the continuous treatment with two chemicals shown in the first embodiment is also effective for the resist removing process after formation of a capacitor insulating film and after formation of an electrode.

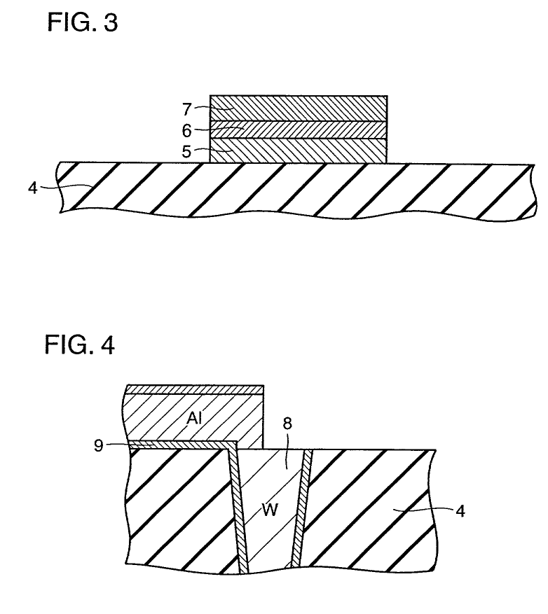

FIG. 3 is a cross sectional view of a wafer after formation of a capacitor insulating film and after formation of an electrode, to which the present invention is applied. A capacitor formed of a lower electrode 5, a capacitor insulating film 6 and an upper electrode 7 is provided on an interlayer insulating film 4. Capacitor insulating film 6 is formed of SiO₂, SiON, SiN, Ta₂O₅, BST, and PZT. Polysilicon, TiN, W, WN, TaN, Ru, Pt, Pt/Ir alloy and the like is used as an electrode material.

The resist-removing process in accordance with the present invention is effective for the resist-residue removing step after formation of the capacitor insulating film and electrodes shown in FIG. 3. It is also effective for the resist removing step after formation of an opening hole after an interlayer insulating film is deposited on the capacitor. Here, the chemicals with strong residue-removability for removing the surface deteriorated layer and the chemicals with strong removability of the bulk resist are respectively the same with those used in the first embodiment.

In accordance with the present embodiment, degradation of capacitor characteristics, such as reduced capacitance of capacitor, increased leak current and decreased charge holding time, which is caused by deterioration of a capacitor insulating film and deterioration due to oxidation of an electrode material, can be prevented.

(Third Embodiment)

The resist-removing process by the continuous treatment using two chemicals shown in the first embodiment is also effective for the resist-removing step after formation of an interconnection and an opening hole.

FIGS. 4, 5, 6, and 7 show the steps to which the present invention is applicable.

FIG. 4 is a cross sectional view of a semiconductor device showing a wafer after an Al interconnection is formed and then resist is removed. Referring to FIG. 4, a W interconnection 8 is provided in interlayer insulating film 4. The Al interconnection is provided above interlayer insulating film 4 with a barrier metal 9 interposed. The Al interconnection is connected to W interconnection 8. The Al interconnection is formed, for example, by depositing Ti, TiN, AlCu, Ti and TiN in order, and then etching these.

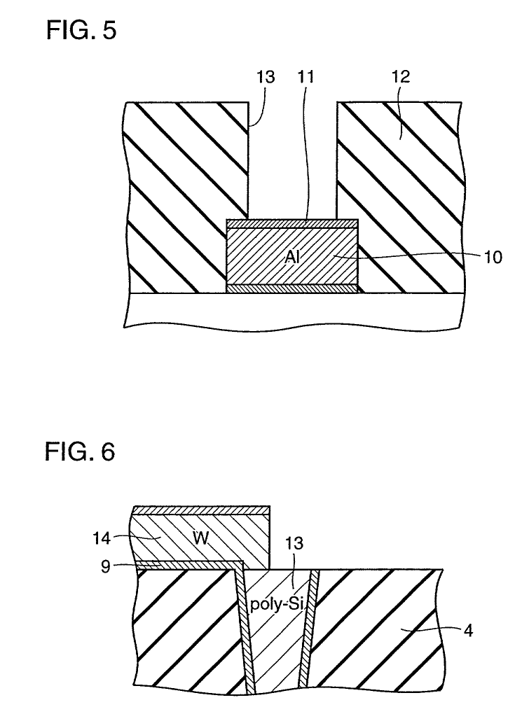

Referring to FIG. 5, an aluminum interconnection 10 is covered over with an interlayer insulating film 12 with a barrier metal 11 interposed. A contact hole 13 is provided in interlayer insulating film 12 using a resist pattern (not shown) as a mask.

Referring to FIG. 6, polysilicon 13 is buried in interlayer insulating film 4. A W interconnection 14 is provided on interlayer insulating film 4 with barrier metal 9 interposed. W interconnection 14 is connected to polysilicon 13.

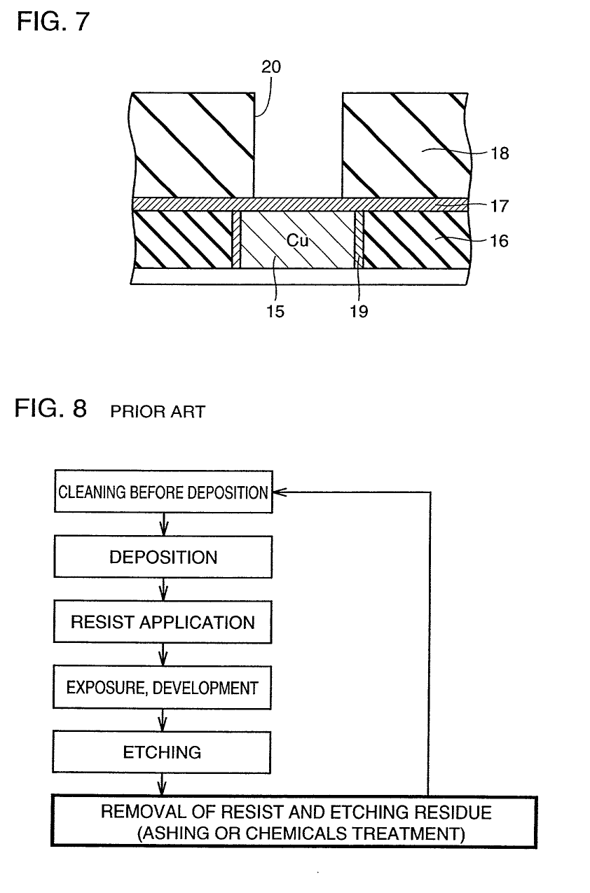

Referring to FIG. 7, in an interlayer insulating film 16, a Cu interconnection 15 is provided surrounded with barrier metal 19. Cu interconnection 15 is coated with a Cu protection film (SiN) 17. On interlayer insulating film 16, an interlayer insulating film 18 is provided with Cu protection film 17 interposed. A contact hole 20 is formed in interlayer insulating film 18. It is noted that contact hole 20 is formed using a resist pattern (not shown) as a mask.

In each step shown in FIGS. 4 to 7, the resist-removing process using the continuous treatment with two chemicals in the present invention may be used, so that etching, oxidation or deterioration of an interconnection material and an interlayer insulating film material can be prevented, and therefore increased interconnection resistance and reduced reliability of interconnection caused by these can be prevented.

In particular, when Low-k material having an organic polymer type structure is used for an interlayer insulating film, oxide ashing cannot be performed. Therefore, in such a case, the resist removal only with chemicals and the resist-residue removing technique in accordance with the present invention that eliminates the need for ashing is effective.

Again, the chemicals with strong residue-removability for removing the surface-deteriorated layer and the chemicals with strong removability of the bulk resist are respectively the same with those used in the first embodiment.

(Effect of the Invention)

As described above, the present invention allows for resist-removal without etching a peripheral material and damaging the peripheral material. Accordingly, a semiconductor device with excellent electric characteristics can be obtained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device, comprising:
a first step of forming a resist pattern on a substrate;
a second step of etching said substrate using said resist pattern as a mask;
a third step of performing a first chemicals treatment for removing a surface-deteriorated layer of said resist pattern; and
a fourth step of performing a second chemicals treatment for removing a bulk portion of said resist pattern.

2. The method of manufacturing a semiconductor device according to claim 1, wherein
said first chemicals treatment is performed with chemicals including at least an organic solvent, a compound including NH₄F and amine, and water.

3. The method of manufacturing a semiconductor device according to claim 1, wherein
said second chemicals treatment is performed with chemicals including an organic solvent and a compound including amine, and not including water.

4. The method of manufacturing a semiconductor device according to claim 1, wherein
said substrate has a structure formed by stacking metal, polysilicon and an insulating film.

5. The method of manufacturing a semiconductor device according to claim 1, wherein
said substrate has a structure formed of a conductive film for lower electrode, a capacitance insulating film and a conductive film for upper electrode.

6. The method of manufacturing a semiconductor device according to claim 1, wherein
said substrate has a structure in which an interlayer insulating film is formed on a capacitor consisted of a lower electrode, a capacitor insulating film and an upper electrode, and said second step is a step of etching said interlayer insulating film to form a connection hole reaching to said upper electrode.

7. The method of manufacturing a semiconductor device according to claim 1, wherein
said first and second steps include forming an interconnection using a resist pattern.

8. The method of manufacturing a semiconductor device according to claim 4, wherein
said first and second steps include the steps of:
forming an interlayer insulating film to cover an interconnection; and
forming a contact hole in said interlayer insulating film.

9. The method of manufacturing a semiconductor device according to claim 1, wherein
said substrate has a structure in which an interlayer insulating film is formed above a buried interconnection with a protection film formed thereon, and said second step is an etching step for forming a contact hole reaching to the protection film on said buried interconnection.

10. The method of manufacturing a semiconductor device according to claim 6, wherein
said interlayer insulating film is an organic polymer film.

11. A method of manufacturing a semiconductor device, comprising the steps of:
forming a resist pattern on a substrate:
implanting ions in the surface of said substrate using said resist pattern as a mask;
performing a first chemicals treatment for removing a surface-deteriorated layer on said resist pattern; and
performing a second chemicals treatment for removing a bulk portion of said resist pattern.

12. A semiconductor device resulting from the following steps of:
(1) forming a resist pattern on a substrate;
(2) etching said substrate using said resist pattern as a mask;
(3) performing a first chemicals treatment for removing a surface-deteriorated layer of said resist pattern; and
(4) performing a second chemicals treatment for removing a bulk portion of said resist pattern.
